(19) United States
(12) Patent Application Publication
(10) Pub. No.: US 2024/0212985 A1
(43) Pub. Date: Jun. 27, 2024

(54) FILTER CIRCUIT AND PLASMA PROCESSING APPARATUS

(71) Applicant: Tokyo Electron Limited, Tokyo (JP)

(72) Inventors: Taro IKEDA, Nirasaki City (JP); Takeshi ISHIDA, Nirasaki City (JP); Tomoki HONDA, Nirasaki City (JP); Hiroyuki MIYASHITA, Nirasaki City (JP)

(21) Appl. No.: 18/392,205

(22) Filed: Dec. 21, 2023

(30) Foreign Application Priority Data
Dec. 22, 2022 (JP) 2022-205055

(51) Int. Cl. H01J 37/32; H01B 9/00

(52) U.S. Cl. CPC H01J 37/32174; H01B 9/003; H01B 9/006; H01J 37/3211

(57) ABSTRACT

A filter circuit includes a housing made of a conductor and comprising an input port and an output port, each of which comprises an outer conductor and an inner conductor, wherein the housing is configured to have a ground potential together with the outer conductors of the input port and the output port, a first protrusion made of a conductor and connected to the housing, wherein the first protrusion is configured to protrude into the housing, and a power supply line provided within the housing and insulated from the housing. The power supply line includes an input-side conductor which is the inner conductor of the input port, an output-side conductor which is the inner conductor of the output port, and an antenna connected to the input-side conductor and the output-side conductor and formed to surround the first protrusion.

### CROSS-REFERENCE TO RELATED APPLICATION

This application is based upon and claims the benefit of priority from Japanese Patent Application No. 2022-205055, filed on Dec. 22, 2022, the entire contents of which are incorporated herein by reference.

### TECHNICAL FIELD

The present disclosure relates to a filter circuit and a plasma processing apparatus.

### BACKGROUND

Patent Document 1 discloses a plasma processing apparatus that includes a filter unit having a heater power supply line, a coil and a capacitor for attenuating or blocking radio frequency noise entering the heater power supply line via a heating element, and a housing that houses the coil and the capacitor.

### PRIOR ART DOCUMENT

### Patent Document

Patent Document 1: Japanese Patent Laid-Open Publication No. 2014-99585

### SUMMARY

According to one embodiment of the present disclosure, a filter circuit includes a housing made of a conductor and comprising an input port and an output port, each of which comprises an outer conductor and an inner conductor, wherein the housing is configured to have a ground potential together with the outer conductors of the input port and the output port, a first protrusion made of a conductor and connected to the housing, wherein the first protrusion is configured to protrude into the housing, and a power supply line provided within the housing and insulated from the housing, wherein the power supply line includes an input-side conductor which is the inner conductor of the input port, an output-side conductor which is the inner conductor of the output port, and an antenna connected to the input-side conductor and the output-side conductor and formed to surround the first protrusion.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an example of a configuration of a plasma processing apparatus according to a first embodiment of the present disclosure.

FIG. 2 is a cross-sectional view illustrating an example of a configuration of a filter circuit according to the first embodiment.

FIG. 3 is a perspective view illustrating an example of the cross-sectional view of FIG. 2 in a rotated state.

FIG. 4 is a view showing an example of a simulation result of an electric field distribution in the filter circuit according to the first embodiment.

FIG. 5 is a graph showing an example of a frequency characteristic of the filter circuit according to the first embodiment.

FIG. 6 is a view illustrating an example of a simulation result of an electric field distribution in a filter circuit according to Modification 1.

FIG. 7 is a graph showing an example of a frequency characteristic of the filter circuit according to Modification 1.

FIG. 8 is a cross-sectional view illustrating an example of a configuration of a filter circuit according to a second embodiment.

FIG. 9 is a view showing an example of a simulation result of an electric field distribution in the filter circuit according to the second embodiment.

FIG. 10 is a graph showing an example of a frequency characteristic of the filter circuit according to the second embodiment.

FIG. 11 is a cross-sectional view illustrating an example of a configuration of a filter circuit according to a third embodiment.

FIG. 12 is a perspective view illustrating an example of the cross-sectional view of FIG. 11 in a rotated state.

FIG. 13 is a view showing an example of a simulation result of an electric field distribution in the filter circuit according to the third embodiment.

FIG. 14 is a graph showing an example of frequency characteristics of the filter circuit according to the third embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments of a filter circuit and a plasma processing apparatus disclosed herein will be described in detail below with reference to the drawings. The technology disclosed herein is not limited by the following embodiments.

In a plasma processing apparatus, a power supply placed outside a processing container is connected to each of an electrostatic chuck and a heater provided in a substrate support that supports a substrate to be processed. Since the substrate support constitutes a lower electrode for generating plasma, radio frequency (RF) waves for generating plasma may affect power supply lines to the electrostatic chuck and the heater. For this reason, RF filters configured with a coil and a capacitor are inserted into these power supply lines. However, the RF filters configured with a coil and a capacitor have a complicated structure and a large size. Therefore, RF filters that are miniaturized with a simple structure are desired.

### First Embodiment

### [Configuration of Plasma Processing System]

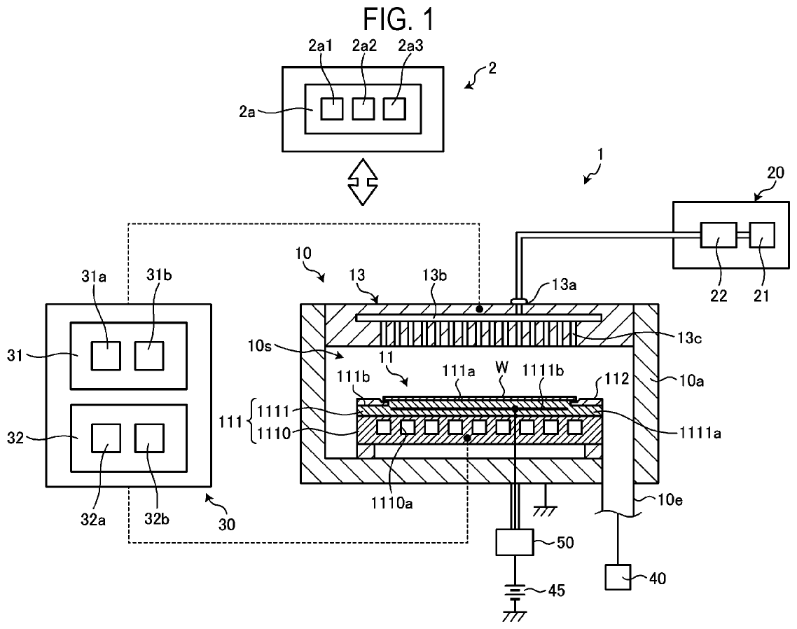

Hereinafter, a configuration example of a plasma processing system will be described. FIG. 1 is a schematic cross-sectional view illustrating an example of a configuration of a plasma processing apparatus according to a first embodiment of the present disclosure. As illustrated in FIG. 1, a plasma processing system includes a capacitively coupled plasma processing apparatus 1 and a controller 2. The capacitively coupled plasma processing apparatus 1 includes a plasma processing chamber 10, a gas supplier 20, a power supply 30, an exhaust system 40, a DC power supply 45, and a filter circuit 50. In addition, the plasma processing apparatus 1 includes a substrate support 11 and a gas introducer. The gas introducer is configured to introduce at least one processing gas into the plasma processing chamber 10. The gas introducer includes a shower head 13. The substrate support 11 is arranged in the plasma processing chamber 10. The shower head 13 is arranged above the substrate support 11. In an embodiment, the shower head 13 constitutes at least a portion of the ceiling of the plasma processing chamber 10. The plasma processing chamber 10 includes a plasma processing space 10s defined by the shower head 13, a side wall 10a of the plasma processing chamber 10, and the substrate support 11. In addition, the plasma processing chamber 10 includes at least one gas supply port configured to supply at least one processing gas to the plasma processing space 10s, and at least one gas discharge port configured to discharge gas from the plasma processing space 10s. The plasma processing chamber 10 is grounded. The shower head 13 and the substrate support 11 are electrically insulated from the housing of the plasma processing chamber 10.

The substrate support 11 includes a main body 111 and a ring assembly 112. The main body 111 includes a central region 111a configured to support a substrate W and an annular region 111b configured to support the ring assembly 112. A wafer is an example of the substrate W. The annular region 111b of the main body 111 surrounds the central region 111a of the main body 111 in a plan view. The substrate W is placed on the central region 111a of the main body 111, and the ring assembly 112 is placed on the annular region 111b of the main body 111 to surround the substrate W on the central region 111a of the main body 111. Accordingly, the central region 111a is also referred to as a “substrate support surface” configured to support the substrate W, and the annular region 111b is also referred to as a “ring support surface” configured to support the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is arranged on the base 1110. The electrostatic chuck 1111 includes a ceramic member 1111a and an electrostatic electrode 1111b disposed inside the ceramic member 1111a. The ceramic member 1111a has a central region 111a. In an embodiment, the ceramic member 1111a also has an annular region 111b. In addition, another member surrounding the electrostatic chuck 1111, such as an annular electrostatic chuck or an annular insulating member, may have the annular region 111b. In this case, the ring assembly 112 may be placed on the annular electrostatic chuck or the annular insulating member, or may be placed on both the electrostatic chuck 1111 and the annular insulating member. The electrostatic electrode 1111b is connected to the DC power supply 45 via the filter circuit 50. When a voltage from the DC power supply 45 is applied to the electrostatic electrode 1111b, electrostatic attraction is generated between the electrostatic chuck 1111 and the substrate W. Due to the generated electrostatic attraction, the substrate W is attracted to and held by the electrostatic chuck 1111.

In addition, at least one RF/DC electrode coupled to an RF power supply 31 and/or a DC power supply 32, which will be described below, may be disposed inside the ceramic member 1111a. In this case, at least one RF/DC electrode functions as the lower electrode. When a bias RF signal and/or a DC signal to be described below is applied to at least one RF/DC electrode, the RF/DC electrode is also called a “bias electrode.” In addition, the conductive member of the base 1110 and at least one RF/DC electrode may function as a plurality of lower electrodes. In addition, the electrostatic electrode 1111b may function as a lower electrode. Accordingly, the substrate support 11 includes at least one lower electrode.

In addition, the substrate support 11 may include a temperature adjusting module configured to adjust a temperature of at least one of the electrostatic chuck 1111, the ring assembly 112, and the substrate W to a target temperature. The temperature adjusting module may include a heater, a heat transfer media, a flow path 1110a, or a combination thereof. A heat transfer fluid, such as brine or gas, flows through the flow path 1110a. In an embodiment, the flow path 1110a is formed inside the base 1110, and one or more heaters are disposed inside the ceramic member 1111a of the electrostatic chuck 1111. In addition, the substrate support 11 may include a heat transfer gas supplier configured to supply a heat transfer gas to the gap between the rear surface of the substrate W and the central region 111a.

The shower head 13 is configured to introduce at least one processing gas from the gas supplier 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introducer may include one or more side gas injectors (SGIs) installed in one or more openings formed in the side wall 10a.

The gas supplier 20 may include at least one gas source 21 and at least one flow rate controller 22. In an embodiment, the gas supplier 20 is configured to supply at least one processing gas from a corresponding gas source 21 to the shower head 13 via the corresponding flow rate controller 22. Each flow rate controller 22 may include, for example, a mass flow controller or a pressure-controlled flow rate controller. In addition, the gas supplier 20 may include one or more flow rate modulation devices configured to modulate or pulsate the flow rate of at least one processing gas.

The power supply 30 includes an RF power supply 31 coupled to the plasma processing chamber 10 via at least one impedance matching circuit. The RF power supply 31 is configured to supply at least one RF signal (RF power) to the at least one lower electrode and/or the at least one upper electrode. As a result, plasma is formed from the at least one processing gas supplied to the plasma processing space 10s. Therefore, the RF power supply 31 may function as at least a portion of a plasma generator configured to generate plasma from one or more processing gases in the plasma processing chamber 10. In addition, by supplying a bias RF signal to the at least one lower electrode, a bias potential can be generated in the substrate W, and an ionic component in the formed plasma can be drawn into the substrate W.

In an embodiment, the RF power supply 31 includes a first RF generator 31a and a second RF generator 31b. The first RF generator 31a is coupled to the at least one lower electrode and/or the at least one upper electrode via at least one impedance matching circuit to generate a source RF signal (source RF power) for plasma generation. In an embodiment, the source RF signal has a frequency in the range of 10 MHz to 300 MHz. In an embodiment, the first RF generator 31a may be configured to generate a plurality of source RF signals having different frequencies. One or more generated source RF signals are provided to the at least one lower electrode and/or the at least one upper electrode.

The second RF generator 31b is coupled to the at least one lower electrode via the at least one impedance matching circuit and is configured to generate a bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in the range of 100 kHz to 60 MHz. In an embodiment, the second RF generator 31b may be configured to generate a plurality of bias RF signals having different frequencies. One or more generated bias RF signals are provided to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a first DC generator 32a and a second DC generator 32b. In an embodiment, the first DC generator 32a is connected to the at least one lower electrode and is configured to generate a first DC signal. The generated first DC signal (bias DC signal) is applied to the at least one lower electrode. In an embodiment, the second DC generator 32b is connected to the at least one upper electrode and is configured to generate a second DC signal. The generated second DC signal is applied to the at least one upper electrode.

In various embodiments, at least one of the first and second DC signals may be pulsed. In this case, a sequence of voltage pulses is applied to the at least one lower electrode and/or the at least one upper electrode. The voltage pulses may have a rectangular pulse waveform, a trapezoidal pulse waveform, a triangular pulse waveform, or a combination thereof. In an embodiment, a waveform generator configured to generate a sequence of voltage pulses from a DC signal is connected between the first DC generator 32a and the at least one lower electrode. Therefore, the first DC generator 32a and the waveform generator constitute a voltage pulse generator. When the second DC generator 32b and the waveform generator constitute a voltage pulse generator, the voltage pulse generator is connected to at least one upper electrode. The voltage pulse may have a positive polarity or a negative polarity. In addition, the sequence of voltage pulses may include one or more positive voltage pulses and one or more negative voltage pulses in one cycle. The first and second DC generators 32a and 32b may be provided in addition to the RF power supply 31, or the first DC generator 32a may be provided in place of the second RF generator 31b.

The exhaust system 40 may be connected to, for example, a gas discharge port 10e provided in a bottom portion of the plasma processing chamber 10. The exhaust system 40 may include a pressure adjusting valve and a vacuum pump. By the pressure adjusting valve, the pressure in the plasma processing space 10s is adjusted. The vacuum pump may include a turbo molecular pump, a dry pump, or a combination thereof.

The filter circuit 50 removes the influence of RF power for plasma generation or bias on the DC power supply 45 when plasma is generated in the plasma processing space 10s. The filter circuit 50 allows the direct current applied to the electrostatic electrode 1111b from the DC power supply 45 to pass therethrough, and blocks the RF power flowing in the opposite direction from the electrostatic electrode 1111b.

The controller 2 processes computer-executable commands that cause the plasma processing apparatus 1 to execute various processes described in the present disclosure. The controller 2 may be configured to control each element of the plasma processing apparatus 1 to perform various processes described herein. In an embodiment, a part or all of the controller 2 may be included in the plasma processing apparatus 1. The controller 2 may include a processor 2a1, a storage 2a2, and a communication interface 2a3. The controller 2 is implemented by, for example, a computer 2a. The processor 2al may be configured to perform various control operations by reading a program from the storage 2a2 and executing the read program. This program may be stored in the storage 2a2 in advance, or may be acquired via a medium when necessary. The acquired program is stored in the storage 2a2, and read from the storage 2a2 and executed by the processor 2a1. The medium may be various storage media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### [Structure of Filter Circuit 50]

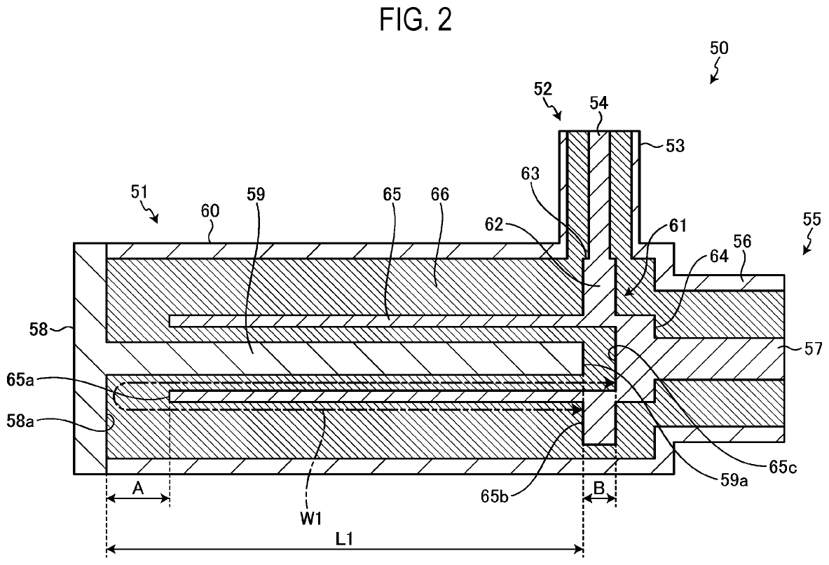

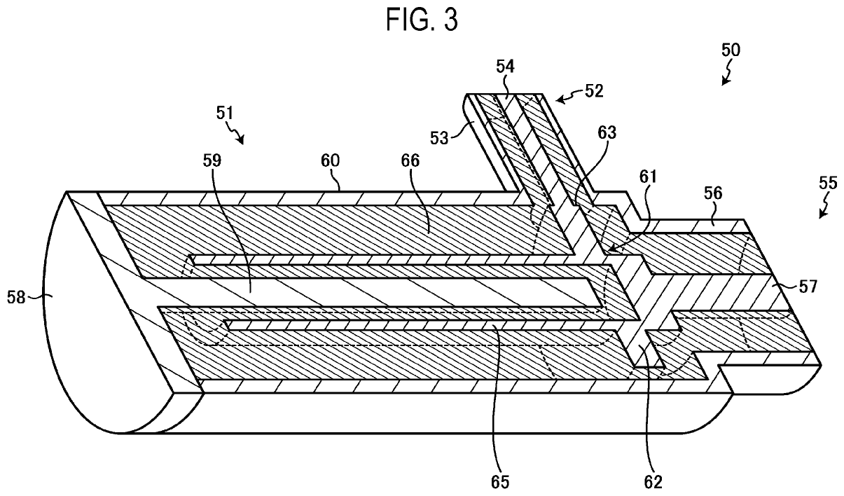

Next, details of the filter circuit 50 will be described with reference to FIGS. 2 and 3. FIG. 2 is a cross-sectional view illustrating an example of a configuration of the filter circuit according to the first embodiment. FIG. 3 is a perspective view illustrating an example of the cross-sectional view of FIG. 2 in a rotated state. As illustrated in FIGS. 2 and 3, the filter circuit 50 has a housing 51. The housing 51 is made of a conductor such as aluminum or copper. In addition, the housing 51 includes an input port 52 and an output port 55. In the present embodiment, since RF power is cut off, the side connected to the electrostatic electrode 1111b will be referred to as the input port 52, and the side connected to the DC power supply 45 will be referred to as the output port 55, with reference to the flow direction of the RF power. In addition, the connection destinations of the input port 52 and the output port 55 may be switched.

The input port 52 and the output port 55 are formed respectively by outer conductors 53 and 56 and inner conductors 54 and 57. That is, the input port 52 and the output port 55 have a coaxial structure. The housing 51 has a ground potential together with the grounded plasma processing chamber 10 via a coaxial cable electrically conducting with the outer conductors 53 and 56 and connected to the input port 52, a frame on which the filter circuit 50 is installed, and the like. The housing 51 has a cylindrical shape, and an input port 52 is formed on a side surface 60 of the cylinder. In addition, the housing 51 may have a cylindrical shape with a square cross section. Moreover, the output port 55 is formed in the cylindrical end of the housing 51 on the side where the input port 52 is formed, and the other end 58 is formed in a disk shape to close the cylinder. In addition, a protrusion 59 formed of a conductor such as aluminum or copper and protruding into the housing 51 is connected to the end 58. The protrusion 59 is an example of the first protrusion, and has, for example, a cylindrical shape.

An antenna 65 formed to surround the protrusion 59 is provided inside the housing 51. The protrusion 59 and the antenna 65 are arranged coaxially. The antenna 65 is made of a conductor such as aluminum or copper, and has a cylindrical shape with one end closed by a base portion 62. That is, the antenna 65 is a cylindrical monopole antenna. In other words, the antenna 65 is an antenna (coaxial insertion monopole antenna) that does not radiate electromagnetic waves at a frequency that is desired to be blocked (cutoff frequency). The base portion 62 is disk-shaped and has a center portion that protrudes to be offset toward the output port 55 side. The inner conductor 54 is connected to the side surface 63 of the base portion 62. The inner conductor 57 is connected to the bottom surface 64 of the base portion 62. That is, the inner conductor (input side conductor) 54 of the input port 52, the inner conductor (output side conductor) 57 of the output port 55, and the antenna 65 form a power supply line 61 that is insulated from the housing 51. That is, in the filter circuit 50, the power supply line 61 formed by the inner conductor 54, the antenna 65, and the inner conductor 57 is arranged at right angles. In addition, the power supply line 61 is a path for supplying a direct current from the DC power supply 45 to the electrostatic electrode 1111b.

A dielectric material 66 is provided between the housing 51 and the power supply line 61. That is, the dielectric material 66 is filled between the protrusion 59 and the antenna 65, between the antenna 65 and the side surface 60 of the cylinder, and between the tip 65a of the antenna 65 and the end 58. Similarly, the dielectric material 66 is filled between the outer conductor 53 and the inner conductor 54 of the input port 52 and between the outer conductor 56 and the inner conductor 57 of the output port 55. As the dielectric material 66, for example, polytetrafluoroethylene (PTFE) or the like may be used.

In addition, in the antenna 65, a space among the housing 51, the protrusion 59, and the antenna 65 from the outer peripheral surface 65b to the center surface 65c of the base portion 62 of the antenna 65 forms a choke structure based on the length of a quarter wavelength of electromagnetic waves to be blocked. That is, a transmission path length W1 from the surface 65b to the surface 65c via the inner surface 58a facing the tip 65a forms a choke structure based on the length of a quarter wavelength of electromagnetic waves to be blocked, a so-called λ/4 choke. That is, since the electromagnetic waves to be blocked travel back and forth along the transmission path length W1, the antenna 65 is a half-wavelength antenna with a length twice the transmission path length W1. The electromagnetic waves may be considered to be radiated from the entire ring-shaped surface 65b. At this time, the length L1 from the surface 65b to the inner surface 58a of the end 58 is expressed by Equations 1 and 2 below, and the transmission path length W1 is expressed by Equation 3 below. In addition, λg is the wavelength of electromagnetic waves, and δ is a parameter for fine adjustment.

$$L 1 = ( λ g / 8 ) + δ \qquad ( 1 )$$

$$- ( 3 / 100 ) λ g ≦ δ ≦ ( 3 / 100 ) λ g \qquad ( 2 )$$

$$W 1 = L 1 \times 2 \qquad ( 3 )$$

Here, a distance A from the tip 65a to the inner surface 58a and a distance B from the tip 59a of the protrusion 59 to the surface 65c are set within the ranges of Equations 4 and 5 below, respectively.

$$0 < A < ( L 1 / 2 ) \qquad ( 4 )$$

$$0 < B < ( L 1 / 2 ) \qquad ( 5 )$$

That is, the distance A from the tip 65a of the antenna 65 to the inner surface 58a of the housing 51 to which the protrusion 59 is connected is less than ½ of the length L1 from the outer peripheral surface 65b of the base portion 62 of the antenna 65 to the inner surface 58a of the housing 51. The distance from the tip 59a of the protrusion 59 to the center surface 65c of the base portion 62 of the antenna 65 is less than ½ of the length L1 from the outer peripheral surface 65b of the base portion 62 of the antenna 65 to the inner surface 58a of the housing 51.

In addition, an example of the length L1 from the surface 65b to the inner surface 58a will be determined. For example, when the frequency of radio frequency power, which is electromagnetic waves to be blocked, is 220 MHz and PTFE with a relative dielectric constant of 2.1 is used as the dielectric material 66, λg=λ/(\sqrt{2.1})=938.5 mm, and λg/8=117.3 mm since λ=1.36 m. Assuming that δ=about −1.3 mm, from Equation 1, L1≅116 mm.

### [Simulation Result]

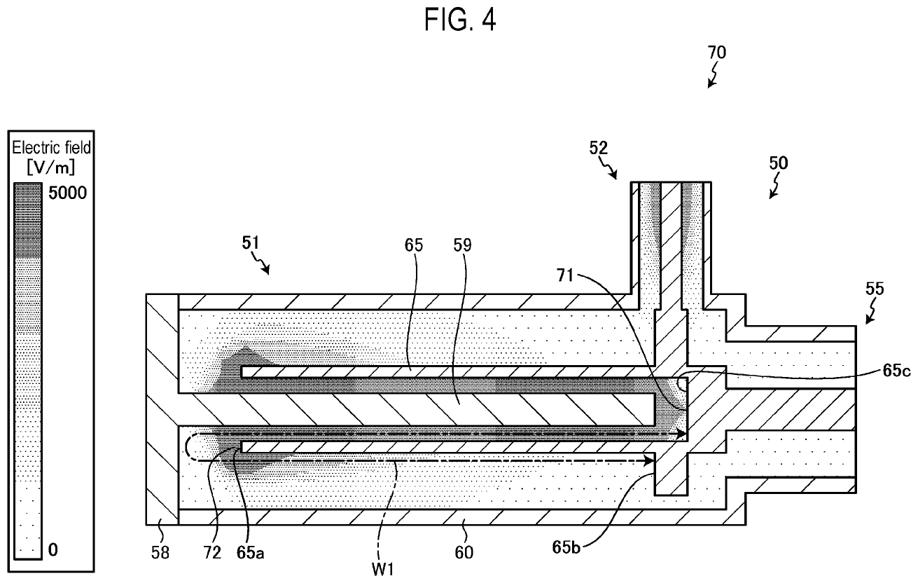

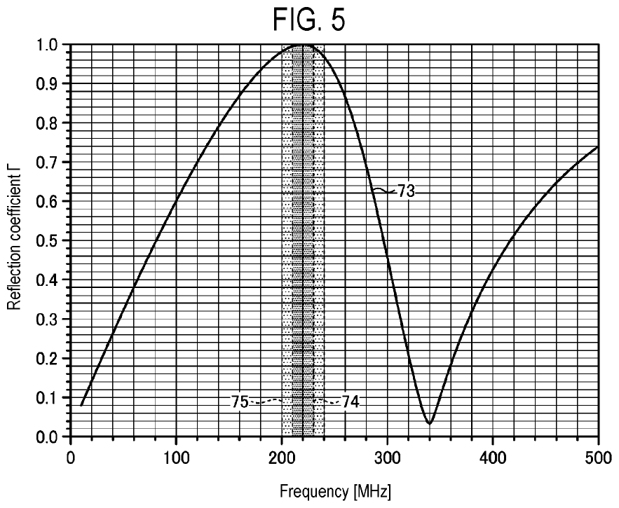

Next, a simulation result of an electric field distribution in the filter circuit 50 will be described with reference to FIGS. 4 and 5. FIG. 4 is a view showing an example of the simulation result of the electric field distribution in the filter circuit according to the first embodiment. The simulation result 70 illustrated in FIG. 4 shows the electric field distribution when an RF power of 220 MHz and 1,000 W is input from the input port 52. In the simulation result 70, in the transmission path length W1 from the surface 65b to the surface 65c, the vicinity of the surface 65c becomes a node 71 of the electromagnetic waves, and the vicinity of the tip 65a becomes an antinode 72 of the electromagnetic waves. At this time, the space between the protrusion 59 and the antenna 65 has a high electric field strength, and the space between the antenna 65 and the side surface 60 has a relatively lower electric field strength than the space between the protrusion 59 and the antenna 65. In addition, in the space between the tip 65a and the end 58, the electric field strength decreases from the tip 65a toward the end 58. In addition, in the vicinity of the output port 55, the electric field strength is almost zero. That is, the protrusion 59 and the antenna 65 within the housing 51 generates reflected waves with a phase shift of 180 degrees from the traveling waves, and the traveling waves and the reflected waves cancel each other out, whereby the output of the RF frequency of 220 MHz from the output port 55 is 0 W.

FIG. 5 is a graph showing an example of a frequency characteristic of the filter circuit according to the first embodiment. Graph 73 shown in FIG. 5 represents the frequency characteristic of the filter circuit 50 in terms of a reflection coefficient Γ. As shown in Graph 73, an attenuation rate of the filter circuit 50 reaches its peak at 220 MHz, which is −22 dB. In addition, the attenuation rate in a range 74 from 210 MHz to 230 MHz is −16 dB. In addition, the attenuation rate in a range 75 from 200 MHz to 240 MHz is −12 dB. That is, the filter circuit 50 forms a band-stop filter with a center frequency of 220 MHz. In this way, since the three-dimensional circuit using a monopole antenna resonates RF waves having a frequency that is desired to be blocked, a filter circuit for high-output RF power, such as 1,000 W in the very high frequency (VHF) band, can be miniaturized with a simple structure. In addition, since the power supply line 61 is insulated from the housing 51, the output of the DC power supply 45 can be applied to the electrostatic electrode 1111b without causing a ground fault.

### [Modification 1]

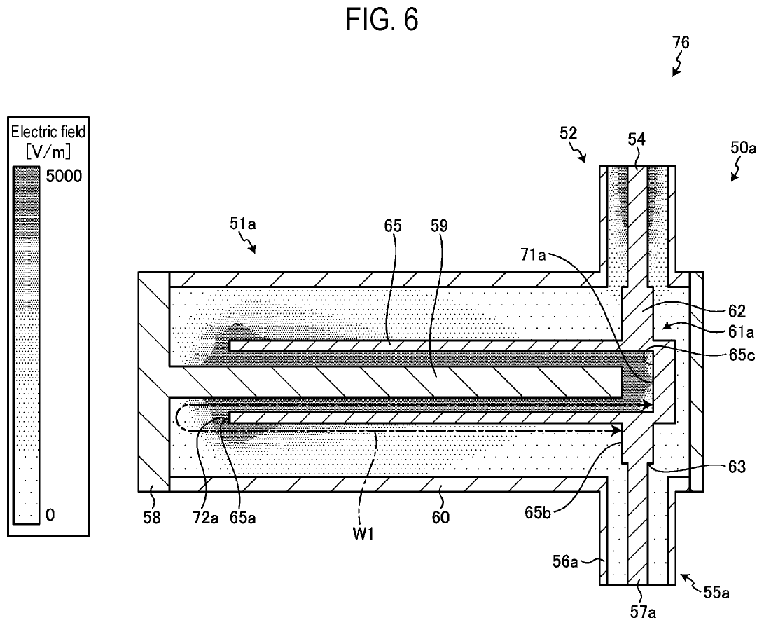

Here, Modification 1 in which the position of the output port 55 is changed will be described. FIG. 6 is a view illustrating an example of a simulation result of an electric field distribution in a filter circuit according to Modification 1. Portions that are different in configuration from the filter circuit 50 will also be described with reference to FIG. 6. In a filter circuit 50a illustrated in FIG. 6, an output port 55a is located on the side surface 60 of the cylinder of the housing 51a, which is opposite to an input port 52. The output port 55a is formed by an outer conductor 56a and an inner conductor 57a. In the housing 51a, the end of the cylinder on the side where the input port 52 and the output port 55a are formed is closed. The outer conductor 56a electrically communicates with the housing 51a. The inner conductor 57a is connected to a side surface 63 of a base portion 62. That is, in the filter circuit 50a, a power supply line 61a formed by an inner conductor 54, an antenna 65, and the inner conductor 57a is arranged on a straight line.

A simulation result 76 illustrated in FIG. 6 shows an electric field distribution when an RF power of 220 MHz and 1,000 W is input from the input port 52. In the simulation result 76, in the transmission path length W1 from the surface 65b to the surface 65c, the vicinity of the surface 65c becomes a node 71a of the electromagnetic waves, and the vicinity of the tip 65a becomes an antinode 72a of the electromagnetic waves. At this time, the space between the protrusion 59 and the antenna 65 has a high electric field strength, and the space between the antenna 65 and the side surface 60 has a relatively lower electric field strength than the space between the protrusion 59 and the antenna 65. In addition, in the space between the tip 65a and the end 58, the electric field strength decreases from the tip 65a toward the end 58. In addition, in the vicinity of the output port 55a, the electric field strength is almost zero. That is, the protrusion 59 and the antenna 65 within the housing 51a generate reflected waves with a phase shift of 180 degrees from the traveling waves, and the traveling waves and the reflected waves cancel each other out, whereby the output of the RF power of 220 MHz from the output port 55a is 0 W.

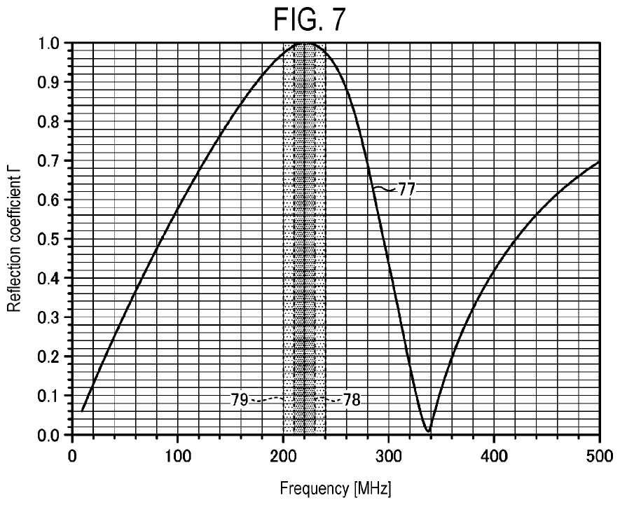

FIG. 7 is a graph showing an example of a frequency characteristic of the filter circuit according to Modification 1. Graph 77 shown in FIG. 7 represents the frequency characteristic of the filter circuit 50a in terms of a reflection coefficient Γ. As shown in Graph 77, an attenuation rate of the filter circuit 50a reaches its peak at 220 MHz, which is −22 dB. In addition, the attenuation rate in a range 78 from 210 MHz to 230 MHz is −16 dB. In addition, the attenuation rate in a range 79 from 200 MHz to 240 MHz is −12 dB. In this way, in Modification 1 as well, since the three-dimensional circuit using a monopole antenna resonates RF waves having a frequency that is desired to be blocked, a filter circuit for high-output RF power, such as 1,000 W in the VHF band, can be miniaturized with a simple structure. In addition, since the power supply line 61a is insulated from the housing 51a, the output of the DC power supply 45 can be applied to the electrostatic electrode 1111b without causing a ground fault.

### Second Embodiment

The antenna 65, which is a monopole antenna, has been used in the above-described first embodiment, but a multipole antenna may also be used, and an embodiment in this case will be described as a second embodiment. Since the plasma processing apparatus in the second embodiment is the same as the above-described first embodiment except for the configuration of the filter circuit, a description of overlapping components and operations will be omitted. In addition, for the filter circuit as well, the same components as those in the first embodiment are designated by the same reference numerals, and a description of overlapping components and operations will be omitted.

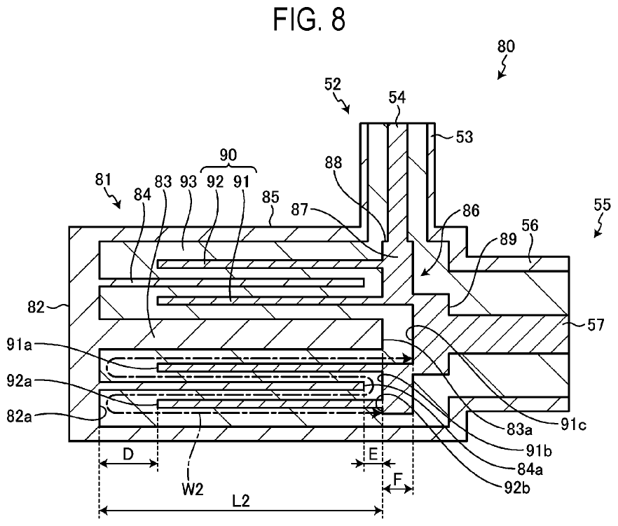

FIG. 8 is a cross-sectional view illustrating an example of a configuration of a filter circuit according to the second embodiment. As illustrated in FIG. 8, a filter circuit 80 has a housing 81. The housing 81 is made of a conductor such as aluminum or copper. In addition, the housing 81 includes an input port 52 and an output port 55. The housing 81 electrically communicates with the outer conductors 53 and 56. The housing 81 has a cylindrical shape, and an input port 52 is formed on a side surface 85 of the cylinder. In addition, the output port 55 is formed in the cylindrical end of the housing 81 on the side where the input port 52 is formed, and the other end 82 is formed in a disk shape to close the cylinder. In addition, protrusions 83 and 84 formed of a conductor such as aluminum or copper and protruding into the housing 81 are connected to the end 82. The protrusion 84 is provided to protrude into the housing 81 around the protrusion 83 in a cylindrical shape. That is, the protrusions 83 and 84 have, for example, a columnar shape and a cylindrical shape which are concentric to each other. In addition, the protrusion 83 is an example of the first protrusion, and the protrusion 84 is an example of the second protrusion.

An antenna 90 is provided inside the housing 81. The antenna 90 has a fin 91 formed to surround the protrusion 83 and a fin 92 formed to surround the protrusion 84. The protrusions 83 and 84 and the fins 91 and 92 are arranged coaxially. The antenna 90 is made of a conductor such as aluminum or copper, and has a cylindrical shape with one end closed by a base portion 87. That is, the antenna 90 is a double cylindrical multipole antenna in which a fin 91 and a fin 92 are connected at the base portion 87. The base portion 87 is disk-shaped and has a center portion that protrudes to be offset toward the output port 55. The inner conductor 54 is connected to the side surface 88 of the base portion 87. The inner conductor 57 is connected to the bottom surface 89 of the base portion 87. That is, the inner conductor (input side conductor) 54 of the input port 52, the inner conductor (output side conductor) 57 of the output port 55, and the antenna 90 form a power supply line 86 that is insulated from the housing 81.

A dielectric material 93 is provided between the housing 81 and the power supply line 86. That is, the dielectric material 93 is filled between the protrusion 83 and the fin 91, between the fin 91 and the protrusion 84, between the protrusion 84 and the fin 92, between the fin 92 and the side surface 85 of the cylinder, and between the tips of the fins 91 and 92 and the end 82. Similarly, the dielectric material 93 is filled between the outer conductor 53 and the inner conductor 54 of the input port 52 and between the outer conductor 56 and the inner conductor 57 of the output port 55. As the dielectric material 93, for example, PTFE or the like may be used.

In addition, in the antenna 90, a space among the housing 81, the protrusions 83 and 84, and the fins 91 and 92 from the outer peripheral surface 92b to the center surface 91c of the base portion 87 of the antenna 90 forms a choke structure based on the length of a quarter wavelength of electromagnetic waves to be blocked. That is, a transmission path length W2 from the surface 92b to the surface 91c via the inner surface 82a facing the tip 92a, the surface 91b, and the inner surface 82a facing the tip 91a forms a choke structure based on the length of a quarter wavelength of electromagnetic waves to be blocked, a so-called λ/4 choke. That is, since the electromagnetic waves to be blocked travel back and forth along the transmission path length W2, the antenna 90 is a half-wavelength antenna with a length twice the transmission path length W2. At this time, the length L2 from the surfaces 91b and 92b to the inner surface 82a of the end 82 is expressed by Equation 6 below, and the transmission path length W2 is expressed by Equation 7 below. In addition, the above-mentioned Equation 2 is used for 8.

$$L 2 = ( λ g / 16 ) + δ \qquad ( 6 )$$

$$W 2 = L 2 \times 4 \qquad ( 7 )$$

Here, a distance D from the tips 91a and 92a to the inner surface 82a, a distance E from the tip 84a of the protrusion 84 to the surface 91b, and a distance F from the tip 83a of the protrusion 83 to the surface 91c are set within the ranges of Equations 8 to 10 below, respectively.

$$0 < D < ( L 2 / 2 ) \qquad ( 8 )$$

$$0 < E < ( L 2 / 2 ) \qquad ( 9 )$$

$$0 < F < ( L 2 / 2 ) \qquad ( 10 )$$

That is, the distance D from the tips 91a and 92a of the fins 91 and 92 to the inner surface 82a of the housing 81 to which the protrusions 83 and 84 are connected is less than ½ of the length L2 from the surfaces 91b and 92b of the base portion 87 of the antenna 90 to the inner surface 82a of the housing 81. The distance E from the tip 84a of the protrusion 84 to the surface 91b of the base portion 87 of the antenna 90 is less than ½ of the length L2 from the surfaces 91b and 92b of the base portion 87 of the antenna 90 to the inner surface 82a of the housing 81. In addition, the distance F from the tip 83a of the protrusion 83 to the center surface 91c of the base portion 87 of the antenna 90 is less than ½ of the length L2 from the surfaces 91b and 92b of the base portion 87 of the antenna 90 to the inner surface 82a of the housing 81.

In addition, an example of the length L2 from the surfaces 91b and 92b to the inner surface 82a will be determined. For example, when the frequency of radio frequency power, which is electromagnetic waves to be blocked, is 220 MHz and PTFE with a relative dielectric constant of 2.1 is used as the dielectric material 93, λg=λ/(√\sqrt{2.1})=938.5 mm, and λg/16=58.7 mm since λ=1.36 m. Assuming that δ=+15.3 mm, from Equation 6, L2≅74 mm.

### [Simulation Result]

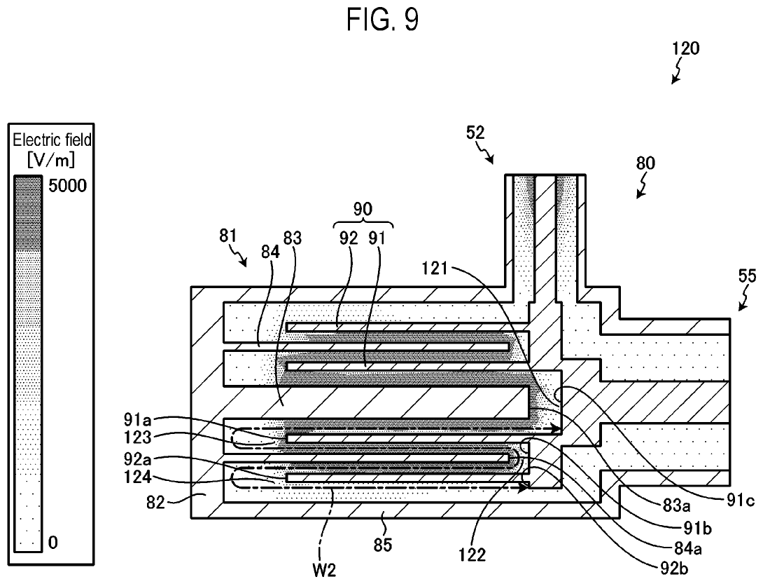

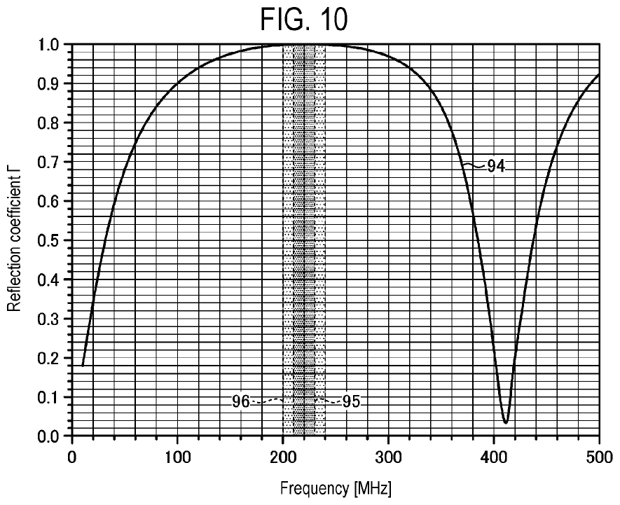

Next, a simulation result of an electric field distribution in the filter circuit 80 will be described with reference to FIGS. 9 and 10. FIG. 9 is a view showing an example of the simulation result of the electric field distribution in the filter circuit according to the second embodiment. The simulation result 120 illustrated in FIG. 9 shows the electric field distribution when an RF power of 220 MHz and 1,000 W is input from the input port 52. In the simulation result 120, in the transmission path length W2 from the surface 92b to the surface 91c, the vicinities of the surfaces 91b and 91c become nodes 121 and 122 of the electromagnetic waves, and the vicinities of the tips 91a and 92a become antinodes 123 and 124 of the electromagnetic waves, respectively. At this time, the electric field strength increases in the space between the protrusion 83 and the fin 91, the space between the fin 91 and the protrusion 84, and the space between the protrusion 84 and the fin 92. In addition, the electric field strength is relatively lower in the space between the fin 92 and the side surface 85 than in the space between the protrusion 83 and the fin 91, the space between the fin 91 and the protrusion 84, and the space between the protrusion 84 and the fin 92. In addition, in the space between the tips 91a and 92a and the end 82, the electric field strength decreases from the tips 91a and 92a toward the end 82. In addition, in the vicinity of the output port 55, the electric field strength is almost zero. That is, the protrusions 83 and 84 and the fins 91a and 92 of the antenna 90 within the housing 81 generate reflected waves with a phase shift of 180 degrees from the traveling waves, and the traveling waves and the reflected waves cancel each other out, whereby the output of the RF power of 220 MHz from the output port 55 is 0 W.

FIG. 10 is a graph showing an example of a frequency characteristic of the filter circuit according to the second embodiment. Graph 94 shown in FIG. 10 represents the frequency characteristic of the filter circuit 80 in terms of a reflection coefficient Γ. As shown in Graph 94, an attenuation rate of the filter circuit 80 reaches its peak at 220 MHz, which is −24 dB. In addition, the attenuation rate in a range 95 from 210 MHz to 230 MHz is −23 dB. In addition, the attenuation rate in a range 96 from 200 MHz to 240 MHz is −20 dB. That is, the filter circuit 80 forms a band-stop filter with a center frequency of 220 MHz. By using a multipole antenna like the antenna 90, the filter circuit 80 has a wider frequency range that can be blocked than the filter circuit 50 of the first embodiment. In this way, since the three-dimensional circuit using a multipole antenna resonates RF waves having a frequency that is desired to be blocked, a filter circuit for high-output RF power, such as 1,000 W in the VHF band, can be miniaturized with a simple structure. In addition, since the power supply line 86 is insulated from the housing 81, the output of the DC power supply 45 can be applied to the electrostatic electrode 1111b without causing a ground fault.

### Third Embodiment

In the second embodiment, the protrusions 83 and 84 are fixed, but the protrusions 83 and 84 may be formed to be inserted into and pulled out from a multipole antenna, and an embodiment in this case will be described as a third embodiment. Since the plasma processing apparatus in the third embodiment is the same as the above-described first embodiment except for the configuration of the filter circuit, a description of overlapping components and operations will be omitted. In addition, for the filter circuit as well, the same components as those in the first embodiment are designated by the same reference numerals, and a description of overlapping components and operations will be omitted.

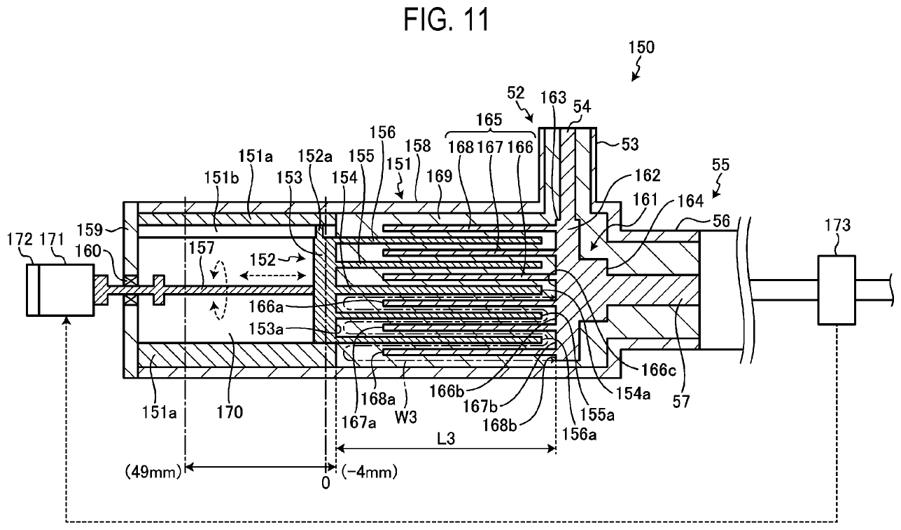

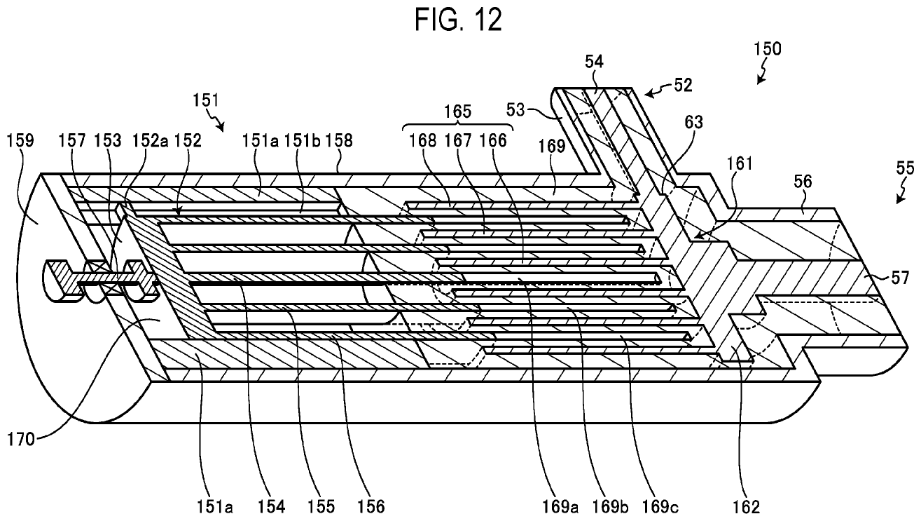

FIG. 11 is a cross-sectional view illustrating an example of a configuration of a filter circuit according to the third embodiment. FIG. 12 is a perspective view illustrating an example of the cross-sectional view of FIG. 11 in a rotated state. As illustrated in FIGS. 11 and 12, a filter circuit 150 has a housing 151. The housing 151 is made of a conductor such as aluminum or copper. In addition, the housing 151 includes an input port 52 and an output port 55. The housing 151 electrically communicates with the outer conductors 53 and 56. The housing 151 has a cylindrical shape, and an input port 52 is formed on a side surface 158 of the cylinder. In addition, the output port 55 is formed in the cylindrical end of the housing 151 on the side where the input port 52 is formed, and the other end 159 is formed in a disk shape to close the cylinder. A bearing 160 is provided at the center of the end 159 and holds the vicinity of the one end of the lead screw 157. The one end of the lead screw 157 is connected to the stepping motor 171 outside the housing 151. The other end of the lead screw 157 is connected to a driving body 152.

The driving body 152 has a base portion 153 and protrusions 154 to 156, which are made of a conductor such as aluminum or copper. The protrusions 154 to 156, which are provided within the housing 151 to protrude toward the output port 55 side, are connected to the base portion 153. The protrusion 155 is provided to protrude into the housing 151 around the protrusion 154 in a cylindrical shape. The protrusion 156 is provided to protrude into the housing 151 around the protrusion 155 in a cylindrical shape. That is, the protrusions 154 to 156 have, for example, a columnar shape and a cylindrical shape which are concentric to each other. In addition, the protrusion 154 is an example of the first protrusion, and the protrusions 155 and 156 are an example of the second protrusion.

An antenna 165 is provided inside the housing 151. The antenna 165 includes a fin 166 formed to surround the protrusion 154, a fin 167 formed to surround the protrusion 155, and a fin 168 formed to surround the protrusion 156. The protrusions 154 to 156 and the fins 166 to 168 are arranged coaxially. The antenna 165 is made of a conductor such as aluminum or copper, and has a cylindrical shape with one end closed by a base portion 162. That is, the antenna 165 is a triple cylindrical multipole antenna in which the fins 166 to 168 are connected to the base portion 162. The base portion 162 is disk-shaped, and the center portion protrudes toward the output port 55. The inner conductor 54 is connected to the side surface 163 of the base portion 162. The inner conductor 57 is connected to the bottom surface 164 of the protruding portion of the base portion 162. That is, the inner conductor (input side conductor) 54 of the input port 52, the inner conductor (output side conductor) 57 of the output port 55, and the antenna 165 form a power supply line 161 that is insulated from the housing 151.

A dielectric material 169 is provided between the housing 151 and the power supply line 161. That is, the dielectric material 169 is filled between the protrusion 154 and the fin 166, between the fin 166 and the protrusion 155, between the protrusion 155 and the fin 167, between the fin 167 and the protrusion 156, and between the protrusion 156 and the fin 168. Similarly, the dielectric material 169 is filled between the fin 168 and the side surface 158 of the cylinder, and between the tip portions 166a to 168a of the fins 166 to 168 and the base portion 153 when the driving body 152 is fully inserted. Similarly, the dielectric material 169 is also filled between the outer conductor 53 and the inner conductor 54 of the input port 52 and between the outer conductor 56 and the inner conductor 57 of the output port 55. As the dielectric material 169, for example, PTFE or the like may be used. A space 170 from the position of the surface 153a of the base portion 153 to the inner surface of the end 159 within the housing 151 in the fully inserted state of the driving body 152 is not filled with the dielectric material 169. In other words, the space 170 becomes a movement space when the driving body 152 is inserted and pulled out.

When the stepping motor 171 rotates, the lead screw 157 also rotates. Thus, the driving body 152 is movable in the space 170 within the housing 151. That is, the driving body 152 is formed to be inserted into and pulled out from the antenna 165. In addition, when the driving body 152 is pulled out toward the end 159 side, the lead screw 157 is received inside the protrusion 154. That is, the protrusion 154 is formed to receive the lead screw 157 therein. When a reference position corresponding to a center of the thickness direction (movement direction) of the base portion 153 is set to “0” in FIG. 11 and the end 159 side is a positive side, the driving body 152 can be inserted and pulled out (moved) within a range of, for example, 0 mm to +49 mm. For example, the driving body 152 illustrated in FIG. 11 is at a fully inserted position of 0 mm, and the driving body 152 illustrated in FIG. 12 is at a fully pulled-out position of +49 mm. After the driving body 152 is pulled out, grooves 169a to 169c are formed corresponding to the protrusions 154 to 156, respectively. That is, no dielectric material 169 is present in the grooves 169a to 169c. In other words, the protrusions 154 to 156 of the driving body 152 are moved along the dielectric material 169 when being inserted into and pulled out from the antenna 165. In this way, by inserting and pulling out the driving body 152, the frequency to be blocked by the filter circuit 150 can be changed.

In addition, the driving body 152 is prevented from rotating together with the lead screw 157 by inserting a protrusion 152a provided on the side surface of the base portion 153 into the groove 151b of the guide 151a in the housing 151. For example, a dielectric material similar to the dielectric material 169 (such as PTFE) may be used for the guide 151a and the protrusion 152a. In addition, a plurality of grooves 151b and protrusions 152a may be provided at positions that are rotationally symmetrical or line symmetrical to suppress bias in electric field. In addition, the guide 151a and the protrusion 152a may have other structures, such as reversing the concave and convex portions, as long as rotation of the driving body 152 can be prevented.

Further, a potentiometer 172 is connected to the stepping motor 171. The controller 2 detects the position of the driving body 152 based on the output value of the potentiometer 172. In addition, in the third embodiment, a power meter 173 may be provided between the output port 55 of the filter circuit 150 and the DC power supply 45 to measure traveling wave power that has passed through the filter circuit 150. In this case, the controller 2 controls the stepping motor 171 based on the RF power measured by the power meter 173 such that the RF power measured by the power meter 173 decreases. That is, the controller 2 can adjust the frequency that is blocked by the filter circuit 150.

In addition, in the antenna 165, a space among the base portion 153, the protrusions 154 to 156, the side surface 158, and the fins 166 to 168 from the outer peripheral surface 168b of the base portion 162 to the center surface 166c forms a choke structure based on the length of a quarter wavelength of the electromagnetic waves to be blocked. That is, the transmission path length W3 extends from the surface 168b to the surface 166c via the vicinity of the tip 168a, the surface 167b, the surface 153a facing the tip 167a, the surface 166b, and the surface 153a facing the tip 166a. The transmission path length W3 forms a choke structure based on the length of a quarter wavelength of the electromagnetic waves to be blocked. That is, since the electromagnetic waves to be blocked travel back and forth along the transmission path length W3, the antenna 165 is a half-wavelength antenna with a length twice the transmission path length W2. At this time, the length L3 from the surfaces 166b to 168b to the surface 153a is expressed by Equation 11 below, and the transmission path length W3 is expressed by Equation 12 below. In addition, the above-mentioned Equation 2 is used for 8. Further, f is the center frequency to be blocked.

$$L 3 = ( λ g ( f ) / 24 ) + δ \qquad ( 11 )$$

$$W 3 = L 3 \times 6 \qquad ( 12 )$$

### [Simulation Result]

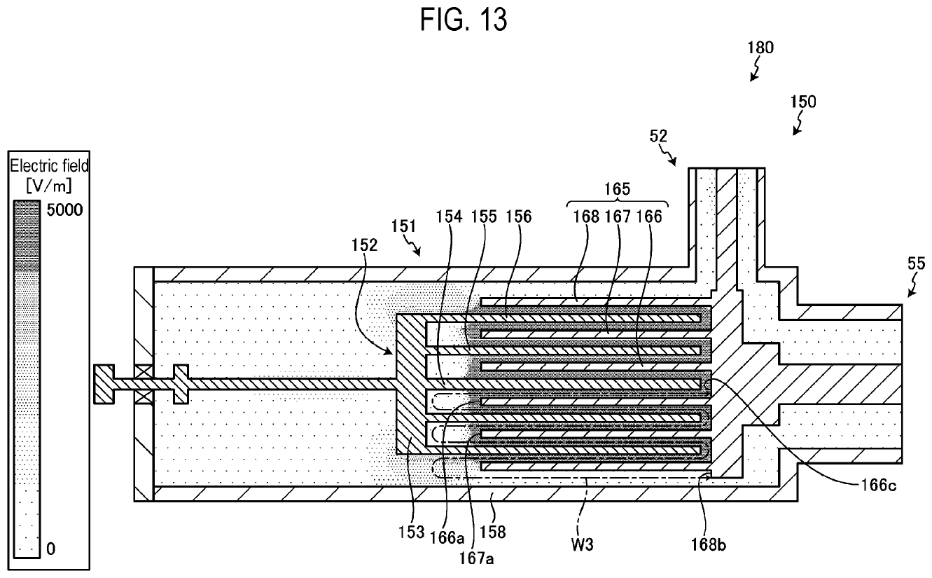

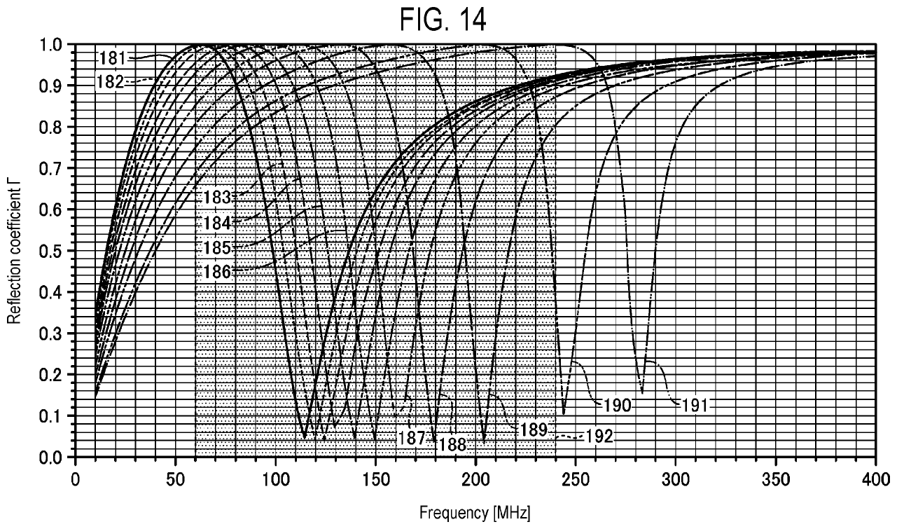

Next, a simulation result of an electric field distribution in the filter circuit 150 will be described with reference to FIGS. 13 and 14. FIG. 13 is a view showing an example of a simulation result of the electric field distribution in the filter circuit according to the third embodiment. The simulation result 180 illustrated in FIG. 13 shows the electric field distribution when an RF power of 60 MHz and 1,000 W is input from the input port 52. In the simulation result 180, in the transmission path length W3 from the surface 168b to the surface 166c, the electric field strength increases in the space between the protrusion 154 and the fin 166, the space between the fin 166 and the protrusion 155, and the space between the protrusion 155 and the fin 167. In addition, the electric field strength also increases in the space between the fin 167 and the protrusion 156 and the space between the protrusion 156 and the fin 168. On the other hand, the electric field strength in the space between the fin 168 and the side surface 158 is relatively lower than that in the space inside the fin 168. In addition, in the space between the tips 166a and 167a and the base portion 153, the electric field strength decreases from the tips 166a and 167a toward the base portion 153. In addition, in the vicinity of the output port 55, the electric field strength is almost zero. That is, the protrusions 154 to 156 of the driving body 152 and the fins 166 to 168 of the antenna 165 generate reflected waves with a phase shift of 180 degrees from the traveling waves, and the traveling waves and the reflected waves cancel each other out, whereby the output of the RF power of 60 MHz from the output port 55 is 0 W.

FIG. 14 is a graph showing an example of frequency characteristics of the filter circuit according to the third embodiment. Graphs 181 to 191 shown in FIG. 14 represent frequency characteristics in terms of a reflection coefficient Γ when the inserted or pulled-out state of the driving body 152 of the filter circuit 150 is changed. Graphs 181 to 191 show frequency characteristics in the case where the driving body 152 is moved from the position of −4 mm to the fully pulled-out position of +49 mm position, assuming the case where the driving body 152 can be inserted further than the fully inserted position of 0 mm, so that the center frequency f to be blocked is 60 MHz to 240 MHz. As shown in Graphs 181 to 191, an attenuation rate of filter circuit 150 is −20 dB or more in a range 192 of 60 MHz to 240 MHz. That is, the filter circuit 150 forms a band-stop filter that can adjust the center frequency to be blocked in the range of 60 MHz to 240 MHz. The filter circuit 150 can handle a plurality of frequencies with respect to the center frequency to be blocked by inserting and pulling out the driving body 152 having the plurality of protrusions 154 to 156 into and from a multipole antenna such as the antenna 165. In this way, since the three-dimensional circuit using a multipole antenna resonates RF waves having a predetermined frequency range that is desired to be blocked, a wideband filter circuit for high-output RF power, such as 1,000 W in the VHF band, can be miniaturized with a simple structure. In addition, since the power supply line 161 is insulated from the housing 151, the output of the DC power supply 45 can be applied to the electrostatic electrode 1111b without causing a ground fault. Furthermore, it is possible to easily adjust the accuracy when fabricating the filter circuit, and it is also possible to cope with a change in the use environment such as temperature.

As described above, according to each embodiment, a filter circuit 50, 50a, 80, or 150 has a housings 51, 51a, 81, or 151, a first protrusion (protrusion 59, 83, or 154), and a power supply line 61, 61a, 86, or 161. The housing 51, 51a, 81, or 151 is made of a conductor and includes an input port 52 and an output port 55 formed by an outer conductor 53 or 56 and an inner conductor 54 or 57, and is configured to have a ground potential together with the conductors 53 and 56 of the input port 52 and the output port 55. The first protrusion is made of a conductor, connected to the housing 51, 51a, 81, or 151, and configured to protrude into the housing 51, 51a, 81, or 151. A power supply line 61, 61a, 86, or 161 is provided within the housing 51, 51a, 81, or 151 and is insulated from the housing 51, 51a, 81, or 151. In addition, the power supply line 61, 61a, 86, or 161 is configured to include an input side conductor which is the inner conductor 54 of the input port 52, an output side conductor which is the inner conductor 57 of the output port 55, and an antenna 65, 90, or 165 which is connected to the input side conductor and the output side conductor and formed to surround the first protrusion. As a result, a filter circuit for high-output RF power can be miniaturized with a simple structure.

In addition, according to each embodiment, a dielectric material 66, 93, or 169 is further provided between the housing 51, 51a, 81, or 151 and the power supply line 61, 61a, 86, or 161. As a result, the total length of the filter circuit 50, 50a, 80, or 150 can be shortened.

In addition, according to each embodiment, the input port and the output port have a coaxial structure. As a result, a filter circuit for high-output RF power can be formed.

In addition, according to the first and second embodiments, the distance from the tip 65a, 91a, or 92a of the antenna 65 or 90 to the inner surface 58a or 82a of the housing 51 or 81 to which the first protrusion is connected is less than the length from the outer peripheral surface 65b or 92b of the base portion 62 or 87 of the antenna 65 or 90 to the inner surface 58a or 82a of the housing 51 or 81. As a result, the total length of the filter circuit 50, 50a, or 80 can be shortened.

In addition, according to the first and second embodiments, the distance from the tip 59a or 83a of the first protrusion to the center surfaces 65c or 91c of the base portion 62 or 87 of the antenna 65 or 90 is less than the length from the outer peripheral surface 65b or 92b of the base portion 62 or 87 to the inner surface 58a or 82a of the housing 51 or 81. As a result, the total length of the filter circuit 50, 50a, or 80 can be shortened.

According to the first embodiment, the antenna 65 is a cylindrical monopole antenna. As a result, RF power can be blocked at a frequency to be blocked.

In addition, according to the first embodiment, the space among the housing 51, the first protrusion, and the antenna 65 from the outer peripheral surface 65b to the center surface 65c of the base portion 62 of the antenna 65 forms a choke structure based on the length of a quarter wavelength of electromagnetic waves to be blocked. As a result, RF power can be blocked at a frequency to be blocked.

In addition, the second embodiment further includes a second protrusion made of a conductor, connected to the housing 81, and configured to protrude into the housing 81 around the first protrusion in a cylindrical shape, and the antenna 90 is a cylindrical multipole antenna that further surrounds the second protrusion. As a result, the frequency range to be blocked can be expanded.

In addition, according to the second embodiment, the space among the housing 81, the first and second protrusions, and the antenna 90 from the outer peripheral surface 92b to the center surface 91c of the base portion 87 of the antenna 90 forms a choke structure based on the length of a quarter wavelength of electromagnetic waves to be blocked. As a result, RF power can be blocked at a frequency to be blocked.

In addition, according to the third embodiment, the first protrusion (protrusion 154) and the second protrusion (protrusions 155 and 156) are formed to be inserted into and pulled out from a multipole antenna (the antenna 165). As a result, a wideband filter circuit for high-output RF power can be miniaturized with a simple structure.

In addition, according to the third embodiment, the first protrusion is formed to receive therein the lead screw 157 connected to the housing 151. As a result, the frequency band to be blocked can be easily changed.

In addition, the third embodiment is configured such that a dielectric material 169 is provided between the multipole antenna and the first and second protrusions, and the first and second protrusions move along the dielectric material 169 when being inserted into and pulled out from the multipole antenna. As a result, the protrusions can be inserted and pulled out without bringing the protrusions into contact with the multipole antenna.

It is to be understood that each embodiment disclosed herein is exemplary in all respects and not restrictive. Each of the above-described embodiments may be omitted, replaced, or modified in various forms without departing from the scope and spirit of the appended claims.

In addition, in each of the above-described embodiments, the transmission path lengths W1, W2, and W3 are set to a quarter wavelength of the electromagnetic waves to be blocked, but the present disclosure is not limited thereto. For example, the lengths of a protrusion and an antenna may be set such that a transmission path length Wx, which is expressed by Equation 13 below and at which traveling waves and reflected waves cancel each other out, is obtained.

$$Wx = ( λ g ( 2 n + 1 ) ) / 4 ( n = 0 or more ) \qquad ( 13 )$$

Further, in each of the above-described embodiments, a filter circuit 50, 50a, 80, or 50 is connected to an electrostatic electrode 1111b inside an electrostatic chuck 1111, but the present disclosure is not limited thereto. For example, the filter circuit may be connected to a heater (not illustrated) provided within a substrate support 11.

In addition, in each of the above-described embodiments, a plasma processing apparatus 1 that performs etching or other processes on a substrate W by using capacitively coupled plasma as a plasma source has been described as an example, but the disclosed technology is not limited thereto. The plasma source is not limited to the capacitively-coupled plasma source as long as the plasma source is an apparatus that performs a process on a wafer W by using plasma. Any plasma source such as an inductively-coupled plasma source, a microwave plasma source, or a magnetron plasma source may be used.

According to the present disclosure, a filter can be miniaturized with a simple structure.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

In addition, the present disclosure may also take the following configurations.

(1) A filter circuit including: a housing made of a conductor and including an input port and an output port, each of which includes an outer conductor and an inner conductor, wherein the housing is configured to have a ground potential together with the outer conductors of the input port and the output port; a first protrusion made of a conductor and connected to the housing, wherein the first protrusion is configured to protrude into the housing; and a power supply line provided within the housing and insulated from the housing, wherein the power supply line includes an input-side conductor which is the inner conductor of the input port, an output-side conductor which is the inner conductor of the output port, and an antenna connected to the input-side conductor and the output-side conductor and formed to surround the first protrusion.

(2) The filter circuit of configuration (1), further including a dielectric material provided between the housing and the power supply line.

(3) The filter circuit of configuration (1) or (2), wherein the input port and the output port have a coaxial structure.

(4) The filter circuit of any one of configurations (1) to (3), wherein a distance from a tip of the antenna to an inner surface of the housing to which the first protrusion is connected is less than a length from an outer peripheral surface of a base portion of the antenna to the inner surface of the housing.

(5) The filter circuit of any one of configurations (1) to (4), wherein a distance from a tip of the first protrusion to a center surface of a base portion of the antenna is less than a length from an outer peripheral surface of the base portion of the antenna to an inner surface of the housing.

(6) The filter circuit of any one of configurations (1) to (5), wherein the antenna is a cylindrical monopole antenna.

(7) The filter circuit of any one of configurations (1) to (6), wherein a space among the housing, the first protrusion, and the antenna from the outer peripheral surface to a center surface of a base portion of the antenna forms a choke structure based on a length of a quarter wavelength of electromagnetic waves to be blocked.

(8) The filter circuit of configuration (1), further including a second protrusion made of a conductor and connected to the housing, wherein the second protrusion is configured to protrude into the housing around the first protrusion in a cylindrical shape, wherein the antenna is a cylindrical multipole antenna that also surrounds the second protrusion.

(9) The filter circuit of configuration (8), further including a space among the housing, the first protrusion, the second protrusion, and the antenna from an outer peripheral surface to a center surface of a base portion of the antenna forms a choke structure based on a length of a quarter wavelength of electromagnetic waves to be blocked.

(10) The filter circuit of configuration (8) or (9), wherein the first protrusion and the second protrusion are formed to be inserted into and pulled out from the multipole antenna.

(11) The filter circuit of configuration (10), wherein the first protrusion is formed to receive therein a lead screw connected to the housing.

(12) The filter circuit of configuration (10) or (11), further including a dielectric material provided between the multipole antenna, and the first protrusion and the second protrusion, wherein the first protrusion and the second protrusion move along the dielectric material when being inserted into and pulled out from the multipole antenna.

(13) A plasma processing apparatus including: a processing container; an electrode which is provided in the processing container and to which two or more types of frequencies are applied; and a filter circuit, wherein the filter circuit includes a housing made of a conductor and including an input port and an output port, each of which includes an outer conductor and an inner conductor, wherein the housing is configured to have a ground potential together with the outer conductors of the input port and the output port, a first protrusion made of a conductor and connected to the housing, wherein the first protrusion is configured to protrude into the housing, and a power supply line provided within the housing and insulated from the housing, wherein the power supply line includes an input-side conductor which is the inner conductor of the input port; an output-side conductor which is the inner conductor of the output port, and an antenna connected to the input-side conductor and the output-side conductor and formed to surround the first protrusion.

What is claimed is:

1. A filter circuit comprising:
a housing made of a conductor and comprising an input port and an output port, each of which comprises an outer conductor and an inner conductor, wherein the housing is configured to have a ground potential together with the outer conductors of the input port and the output port;
a first protrusion made of a conductor and connected to the housing, wherein the first protrusion is configured to protrude into the housing; and
a power supply line provided within the housing and insulated from the housing,
wherein the power supply line comprises:
an input-side conductor which is the inner conductor of the input port;
an output-side conductor which is the inner conductor of the output port; and
an antenna connected to the input-side conductor and the output-side conductor and formed to surround the first protrusion.

2. The filter circuit of claim 1, further comprising:
a dielectric material provided between the housing and the power supply line.

3. The filter circuit of claim 1, wherein the input port and the output port have a coaxial structure.

4. The filter circuit of claim 1, wherein a distance from a tip of the antenna to an inner surface of the housing to which the first protrusion is connected is less than a length from an outer peripheral surface of a base portion of the antenna to the inner surface of the housing.

5. The filter circuit of claim 1, wherein a distance from a tip of the first protrusion to a center surface of a base portion of the antenna is less than a length from an outer peripheral surface of the base portion of the antenna to an inner surface of the housing.

6. The filter circuit of claim 1, wherein the antenna is a cylindrical monopole antenna.

7. The filter circuit of claim 1, wherein a space among the housing, the first protrusion, and the antenna from an outer peripheral surface of a base portion to a center surface of the base portion of the antenna forms a choke structure based on a length of a quarter wavelength of electromagnetic waves to be blocked.

8. The filter circuit of claim 1, further comprising:
a second protrusion made of a conductor and connected to the housing, wherein the second protrusion is configured to protrude into the housing around the first protrusion in a cylindrical shape,
wherein the antenna is a cylindrical multipole antenna that further surrounds the second protrusion.

9. The filter circuit of claim 8, wherein a space among the housing, the first protrusion, the second protrusion, and the antenna from an outer peripheral surface of a base portion to a center surface of the base portion of the antenna forms a choke structure based on a length of a quarter wavelength of electromagnetic waves to be blocked.

10. The filter circuit of claim 8, wherein the first protrusion and the second protrusion are formed to be inserted into and pulled out from the multipole antenna.

11. The filter circuit of claim 10, wherein the first protrusion is formed to receive therein a lead screw connected to the housing.

12. The filter circuit of claim 10, further comprising:
a dielectric material provided between the multipole antenna, and the first protrusion and the second protrusion,
wherein the first protrusion and the second protrusion move along the dielectric material when being inserted into and pulled out from the multipole antenna.

13. The filter circuit of claim 11, further comprising:
a dielectric material provided between the multipole antenna, and the first protrusion and the second protrusion,
wherein the first protrusion and the second protrusion move along the dielectric material when being inserted into and pulled out from the multipole antenna.

14. A plasma processing apparatus comprising:
a processing container;
an electrode which is provided in the processing container and to which two or more types of frequencies are applied; and
a filter circuit,
wherein the filter circuit comprises:
a housing made of a conductor and comprising an input port and an output port, each of which comprises an outer conductor and an inner conductor, wherein the housing is configured to have a ground potential together with the outer conductors of the input port and the output port;
a first protrusion made of a conductor and connected to the housing, wherein the first protrusion is configured to protrude into the housing; and
a power supply line provided within the housing and insulated from the housing,
wherein the power supply line comprises:
an input-side conductor which is the inner conductor of the input port;
an output-side conductor which is the inner conductor of the output port; and
an antenna connected to the input-side conductor and the output-side conductor and formed to surround the first protrusion.
